(19) United States
(12) Patent Application Publication
(10) Pub. No.: US 2012/0009690 A1
(43) Pub. Date: Jan. 12, 2012

(54) IN-SITU SPECTROMETRY

(75) Inventors: Clement Hsingjen Wann, Carmel, NY (US); Hung-Ming Chen, Hsinchu City (TW); Chang-Yun Chang, Taipei (TW); Sey-Ping Sun, Hsinchu City (TW)

(73) Assignee: TAIWAN SEMICONDUCTOR MANUFACTURING COMPANY, LTD., Hsin-Chu (TW)

(21) Appl. No.: 12/834,617

(22) Filed: Jul. 12, 2010

(51) Int. Cl. H01L 21/66; B08B 3/04

(52) U.S. Cl. 438/8; 134/104.2; 134/94.1; 134/95.1; 257/E21.528

(57) ABSTRACT

The present disclosure provides a system for in-situ spectrometry. The system includes a wafer-cleaning machine that cleans a surface of a semiconductor wafer using a cleaning solution. The system also includes a spectrometry machine that is coupled to the wafer-cleaning machine. The spectrometry machine receives a portion of the cleaning solution from the wafer-cleaning machine. The portion of the cleaning solution collects particles from the wafer during the cleaning. The spectrometry machine is operable to analyze a particle composition of a portion of the wafer based on the portion of the cleaning solution, while the wafer remains in the wafer-cleaning machine during the particle composition analysis.

### TECHNICAL FIELD

The present disclosure relates generally to a method of fabricating a semiconductor device, and more particularly, to a method and system of inspection during semiconductor fabrication.

### BACKGROUND

The semiconductor integrated circuit (IC) industry has experienced rapid growth. Technological advances in IC materials and design have produced generations of ICs where each generation has smaller and more complex circuits than the previous generation. These ICs include high-k metal gate semiconductor devices. The fabrication of the high-k metal gate devices may involve an inspection process to ensure that non-high-k metal gate devices will not be contaminated by particles of the high-k metal device, for example by particles containing metal. Traditionally, this inspection process is performed off-line, which may be cumbersome, may slow down production and waste wafers, and may lack the ability to provide real-time data feedback.

Therefore, while traditional methods of inspecting high-k metal gate devices have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating a method of performing an inspection during the fabrication of a high-k metal gate device according to an embodiment of the present disclosure.

FIG. 2 is a diagrammatic fragmentary cross-sectional side view of a wafer on which a high-k metal gate device is formed according to an embodiment of the present disclosure.

FIGS. 3-5 are respective diagrammatic views of various embodiments of an in-line cleaning and inspection system that is used to clean and analyze the wafer of FIG. 2.

### SUMMARY

One of the broader forms of the present disclosure involves an in-situ spectrometry system. The system includes: a wafer-cleaning machine that cleans a surface of a semiconductor wafer using a cleaning solution; and a spectrometry machine that is coupled to the wafer-cleaning machine and receives a portion of the cleaning solution from the wafer-cleaning machine, the portion of the cleaning solution collecting particles from the wafer during the cleaning; wherein the spectrometry machine is operable to analyze a particle composition of a portion of the wafer based on the portion of the cleaning solution, while the wafer remains in the wafer-cleaning machine during the particle composition analysis.

Another of the broader forms of the present disclosure involves an in-situ spectrometry system. The system includes: a wafer-cleaning apparatus that uses first, second, and third cleaning solutions in that order to clean a surface of a semiconductor wafer, the first, second, and third cleaning solutions being different from one another, the wafer having semiconductor gates formed thereon that contain a metal material; and a particle-analysis apparatus that: receives a sample of the third cleaning solution after the third cleaning solution has been used to clean the wafer; and determines a content of the metal material in the sample of the third cleaning solution; wherein the wafer stays in the wafer-cleaning apparatus while the particle-analysis apparatus receives the sample of the third cleaning solution and determines the content of the metal material therein.

Still another of the broader forms of the present disclosure involves a method of in-situ inspection. The method includes: forming a gate of a semiconductor device, the gate containing a metal material; cleaning the gate using a cleaning solution, the cleaning solution collecting particles from the gate during the cleaning; and thereafter analyzing a portion of the cleaning solution for particle composition, the analyzing being carried out using an in-situ spectrometry machine.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

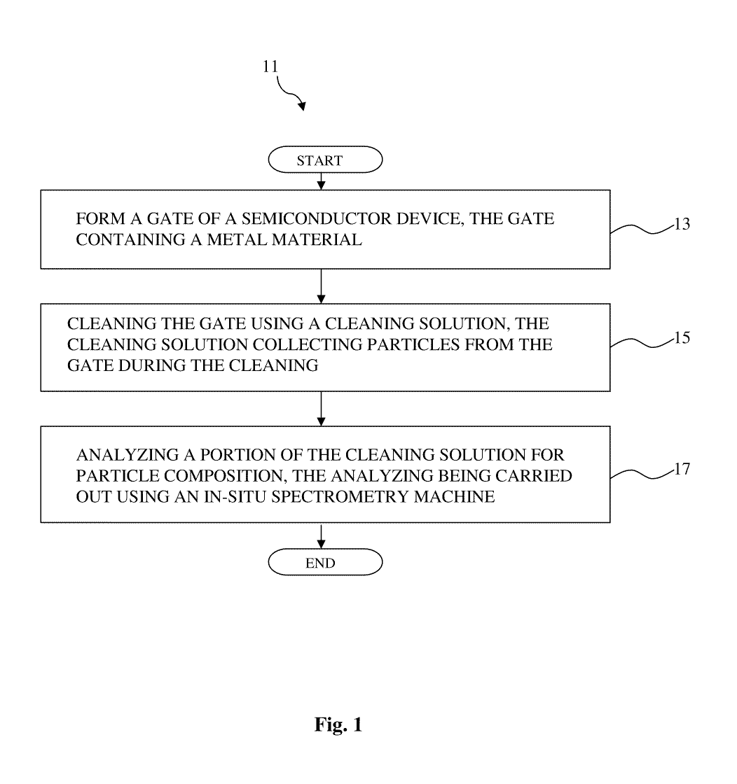

FIG. 1 is a flowchart of a method 11 for inspecting a semiconductor device during its fabrication. The method 11 begins with block 13 in which a gate of a semiconductor device is formed. The gate contains a metal material. The method 11 continues with block 15 in which the gate is cleaned using a cleaning solution. The cleaning solution collects particles from the gate during the cleaning. The method continues with block 17 in which a portion of the cleaning solution is analyzed for particle composition. The analyzing is carried out using an in-situ spectrometry machine. It should be noted that additional processes may be provided before, during, and after the method 11 of FIG. 1, and that some other processes may only be briefly described herein.

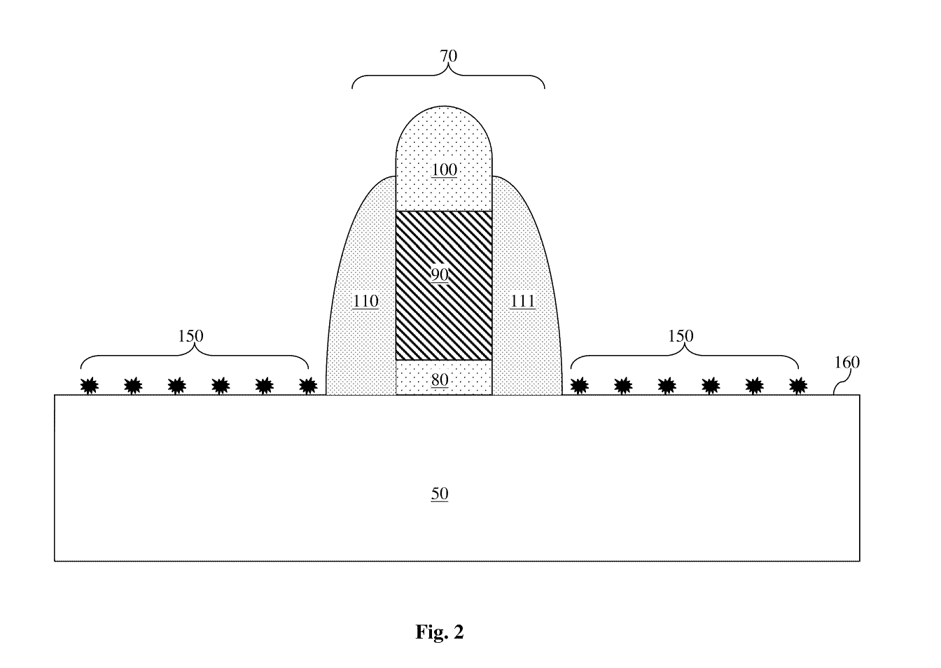

FIG. 2 is a diagrammatic fragmentary cross-sectional side view of a wafer 50 and devices formed thereon. The wafer 50 may be a silicon wafer that is doped either with a P-type dopant such as boron or with an N-type dopant such as arsenic or phosphorous. A gate structure 70 is formed on the wafer 50. In the present embodiment, the gate structure 70 is a high-k metal gate device. The gate structure 70 includes a gate dielectric layer 80, a gate electrode layer 90 formed over the gate dielectric layer 80, a hard mask layer 100 formed over the gate electrode layer 90, and gate spacers 110-111 formed on the sidewalls of the gate dielectric layer 80 and the gate electrode layer 90.

The gate dielectric layer 80 includes a high-k dielectric material. A high-k dielectric material is a material having a dielectric constant that is greater than a dielectric constant of SiO₂, which is approximately 4. For example, the high-k dielectric material may include hafnium oxide (HfO₂), which has a dielectric constant that is in a range from approximately 18 to approximately 40. Alternatively, the high-k material may include one of ZrO₂, Y₂O₃, La₂O₅, Gd₂O₅, TiO₂, Ta₂O₅, HfErO, HfLaO, HfYO, HfGdO, HfAlO, HfZrO, HfTiO, HfTaO, SrTiO, or combinations thereof. The gate dielectric layer 90 may be formed by a process such as chemical vapor deposition (CVD), physical vapor deposition (PVD), atomic layer deposition (ALD), or another suitable technique.

The gate electrode layer 90 includes polysilicon in an embodiment and therefore may serve as a dummy poly gate. In another embodiment, the gate electrode layer 90 may include a work function metal portion and a fill metal portion, in which case it is a metal gate. The work function metal portion may be N-metal such as Ti, Al, Ta, ZrSi₂, TaN, or combinations thereof, or P-metal such as Mo, Ru, Ir, Pt, PtSi, MoN, WNx, or combinations thereof. The work function metal portion of the gate electrode layer 90 has a work function value that is determined by the material composition of the work function metal. Thus, the work function value can be changed (for example by changing the material composition of the work function metal) to tune a work function of the gate structure 70 so that a desired threshold voltage Vₜ is achieved. The fill metal portion of the gate electrode layer 90 includes one of tungsten (W), Aluminum (Al), copper (Cu), and combinations thereof, and serves as the main conductive portion of the gate structure 70. The gate electrode layer 90 may be formed by CVD, PVD, or another suitable technique.

The hard mask layer 100 is used to pattern the gate dielectric layer 80 and the gate electrode layer 90 therebelow using one or more etching processes known in the art. The hard mask layer 100 may include an oxide material or a nitride material. The gate spacers 110-111 are formed using a deposition process and an etching process (for example, an anisotropic etching process) known in the art. The gate spacers 110-111 include a suitable dielectric material such as silicon nitride, silicon oxide, silicon carbide, silicon oxy-nitride, or combinations thereof.

Although not illustrated, there may be a buffer metal layer between the gate dielectric layer 80 and the gate electrode layer 90. The buffer metal layer may include a metal material such as titanium nitride (TiN). In addition, a plurality of other gate structures that are similar to the gate structure 70 may be formed on the wafer 50. For the sake of simplicity, these other gate structures are not illustrated herein.

The various processes employed in forming the gate structure 70 may cause a plurality of contaminant particles 150 to be formed on a front surface 160 of the wafer 50. These contaminant particles 150 may include high-k dielectric particles such as HfO₂ particles, or metal ion particles such as TiN, or organic particles. These contaminant particles 150 need to be removed, or else they may lead to process defects later. For example, they may contaminate non-high-k metal gate devices. An inspection needs to be performed to analyze the material composition of these particles 150. If the observed material composition is out of expected range, then that may indicate a prior fabrication process needs to be tuned.

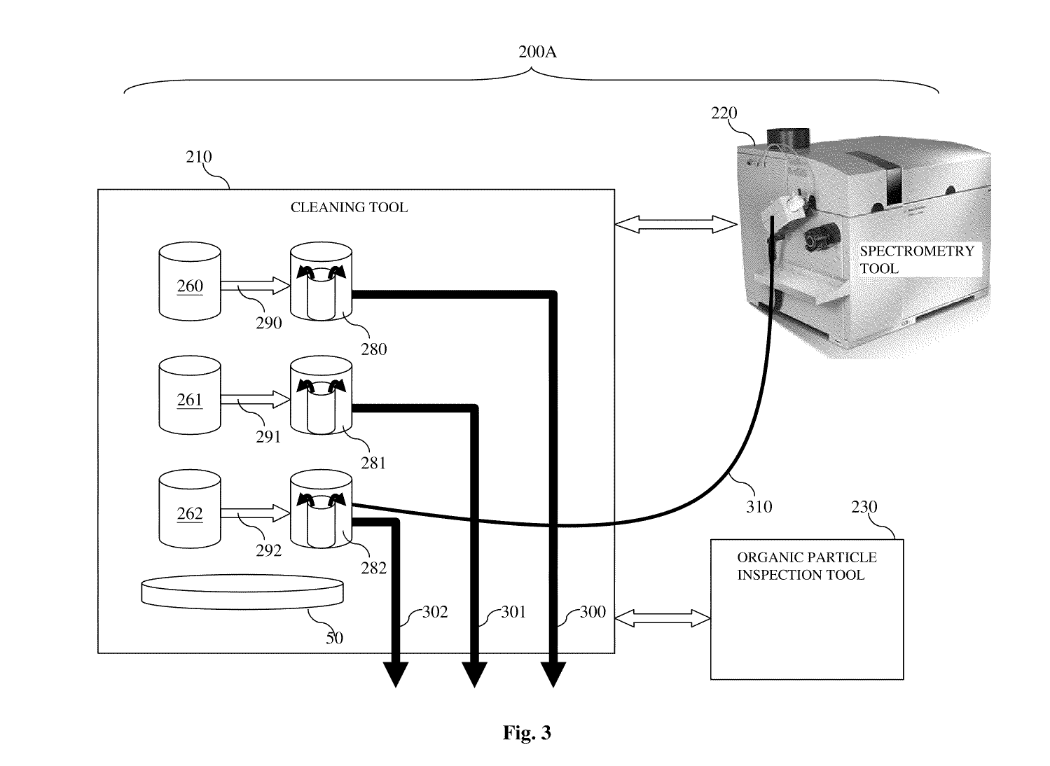

Referring now to FIG. 3, a diagrammatic view of an in-line cleaning and inspection system 200A according to one embodiment is illustrated. The in-line cleaning and inspection system 200A includes a wafer-cleaning tool 210, a spectrometry tool 220, and an organic particle inspection tool 230. These tools 210-230 may also be referred to as machines, apparatuses or components of the system 200A. Each of these tools 210-230 may have one or more computers implemented therein and may have one or more sealable chambers. The spectrometry tool 220 and the organic particle inspection tool 230 are both electrically and communicatively coupled to the cleaning tool 210, so that they may be able to carry out data communication with the cleaning tool. The wafer 50 and the devices formed thereon (such as the gate structure 70 and the contaminant particles 150) are placed inside the wafer-cleaning tool 210 for cleaning.

The wafer-cleaning tool 210 includes three cleaning solution storage and dispensing units 260, 261, and 262. The unit 260 can store and dispense a cleaning solution (or cleaning agent) that contains hydrofluoric acid (HF). The hydrofluoric acid solution helps remove high-k dielectric particles from the wafer, for example HfO₂ particles. Thus, the front surface 160 (shown in FIG. 2) of the wafer 50 is cleaned using the hydrofluoric acid to remove some of the contaminant particles 150.

Thereafter, the wafer 50 is cleaned using the cleaning solution (or cleaning agent) stored in the unit 261. In an embodiment, this cleaning solution is an ammonia and hydrogen peroxide mixture (APM), which may also be referred to as “standard solution 1.” In an embodiment, the APM solution stored and dispensed by the unit 261 includes a mixture of ammonium hydroxide (NH₄OH), hydrogen peroxide (H₂O₂), and de-ionized water (H₂O). An example concentration ratio of such mixture may be about 1:1:5 (NH₄OH:H₂O₂:H₂O), although other ratios be also be used. The APM solution is used to remove certain types of contaminant particles 150, such as TiN particles. The APM solution may accomplish this by continually oxidizing and then etching the surface 160 of the wafer 50, thereby dissolving the targeted contaminant particles 150 into the APM solution.

Thereafter, the wafer 50 is cleaned using the cleaning solution (or cleaning agent) stored in the unit 262. In an embodiment, this cleaning solution is a hydrochloride and hydrogen peroxide mixture (HPM), which may also be referred to as “standard solution 2.” In an embodiment, the HPM solution stored and dispensed by the unit 262 includes a mixture of hydrochloric acid (HCl), hydrogen peroxide (H₂O₂), and de-ionized water (H₂O). An example concentration ratio of such mixture may be about 1:1:5 (HCl:H₂O₂:H₂O), although other ratios be also be used. The HPM solution is used to remove metal impurity contaminant particles 150. Similar to the APM solution, the HPM solution may accomplish this by continually oxidizing and then etching the surface 160 of the wafer 50, thereby dissolving the targeted contaminant particles 150 into the HPM solution.

The wafer cleaning tool 210 also includes sample cups 280, 281, and 282 that may be parts of an auto sampler. The sample cups 280-282 are coupled to the cleaning solution storage and dispensing units 260-262, through pipe lines (or piping) 290-292, respectively. The pipe lines 290-292 may also each include a pump (not illustrated) that can propel the movement of fluids, such as the respective cleaning solutions that are stored in the units 260-262. The pumps may be made to be acid/base proof. The sample cups 280-282 are also coupled to drainage pipes 300-302, respectively.

After the wafer 50 has been cleaned using the HF-containing cleaning solution from the unit 260, the HF-containing cleaning solution is sent to the sample cup 280. In the present embodiment, the HF-containing cleaning solution is then dumped through the drainage pipe 300.

After the wafer 50 has been cleaned using the APM cleaning solution from the unit 261, the APM cleaning solution is sent to the sample cup 281. In the present embodiment, the APM cleaning solution is then dumped through the drainage pipe 301.

After the wafer 50 has been cleaned using the HPM cleaning solution from the unit 262, the HPM cleaning solution is sent to the sample cup 282. In the present embodiment, a portion of the HPM cleaning solution is sent to the spectrometry tool 220 for particle analysis. The spectrometry tool 220 is coupled to the sample cup 282 through a hose 310. The rest of the HPM cleaning solution may then be dumped through the drainage pipe 302.

In an embodiment, the spectrometry tool 220 includes an inductively coupled plasma mass spectrometry (ICP-MS) tool. Such tool can be used to determine the elemental or material composition of a sample, where the sample may be the HPM cleaning solution from the sample cup 282. The sample of the HPM cleaning solution received by the spectrometry tool 220 was already used to clean the wafer 50. During the cleaning process, the cleaning solution would have collected samples of the contaminant particles 150 (shown in FIG. 2) from the wafer surface. Therefore, the spectrometry tool 220 can be used to analyze the material composition of the contaminant particles 150 based on the received sample of the HPM cleaning solution, such as the content of metals such as Cr, Ni, Co, Cu, Ti, Ge, Mo, Ru, Hf, Ta, La, Zr, or W. For example, the amount of the particles for each of these metals may be determined by analyzing the HPM solution sample. In some embodiments, the content of dielectric materials may also be determined by analyzing the HPM solution.

The spectrometry analysis can be performed quickly, for example in a matter of seconds. When the analysis is complete, the analysis results can then be fed back in real-time to the cleaning tool 210. In response to the analysis results, the cleaning tool 210 may make adjustments to one or more of the cleaning processes discussed above. Note that the collection of the HPM cleaning solution sample, the analysis of the HPM cleaning solution sample, the analysis result feedback, and the cleaning process adjustment are all performed while the wafer 50 remains inside the cleaning tool 210. Therefore, the spectrometry tool 220 may also be referred to as an in-situ or an in-line spectrometry tool.

The organic particle inspection tool 230 includes an organic carbon analyzer in an embodiment. Similar to the spectrometry tool 220, the organic particle inspection tool 230 may be operable to receive samples of the cleaning solutions from any of the sample cups 280-282. Based on these samples, the organic particle inspection tool 230 may analyze the material composition of the contaminant particles 150, with respect to the content of organic compounds.

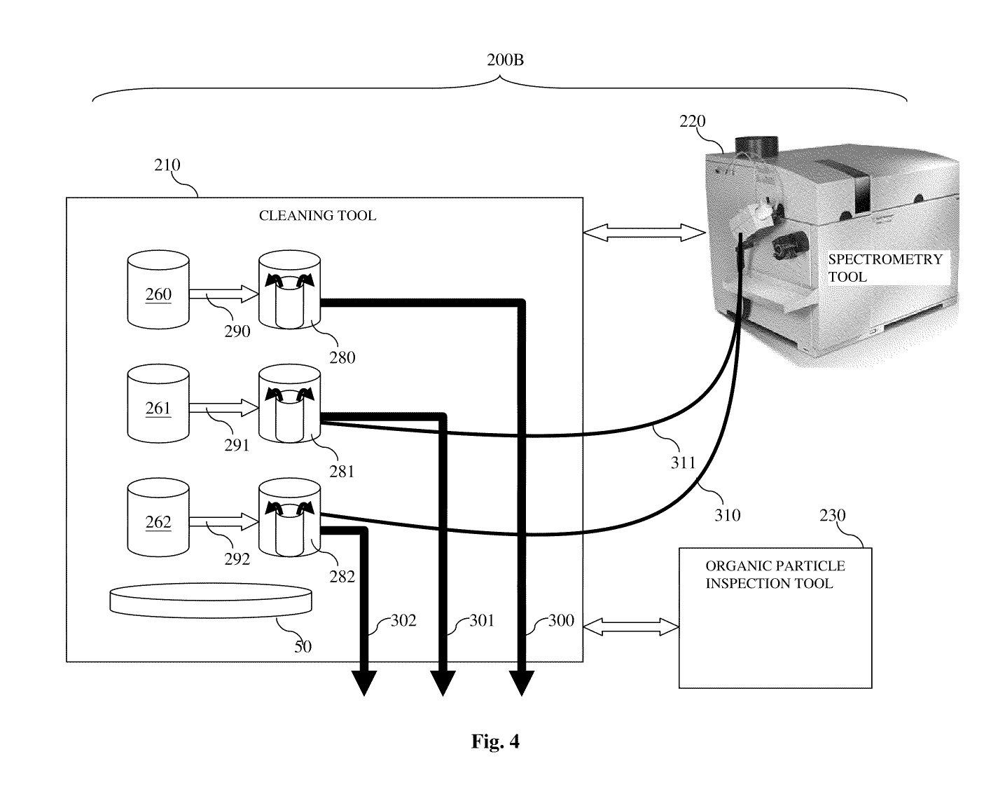

Referring now to FIG. 4, a diagrammatic view of an in-line cleaning and inspection system 200B according to an alternative embodiment is illustrated. This embodiment of the in-line cleaning and inspection system 200B is similar to the system 200A discussed above, and thus similar components are labeled the same for the sake of consistency and clarity. One difference between the systems 200A and 200B is that, in the system 200B, not all of the APM cleaning solution is dumped after its use. Instead, a portion of the APM cleaning solution is also saved and sent to the spectrometry tool 220 for analysis through a hose 311, in a manner similar to the HPM solution. Thus, in the embodiment illustrated in FIG. 4, the spectrometry tool 220 will carry out the material composition analysis of the contaminant particles 150 based on both the APM cleaning solution as well as the HPM cleaning solution. Note that the wafer 50 still remains inside the cleaning tool 210 while the spectrometry analysis takes place.

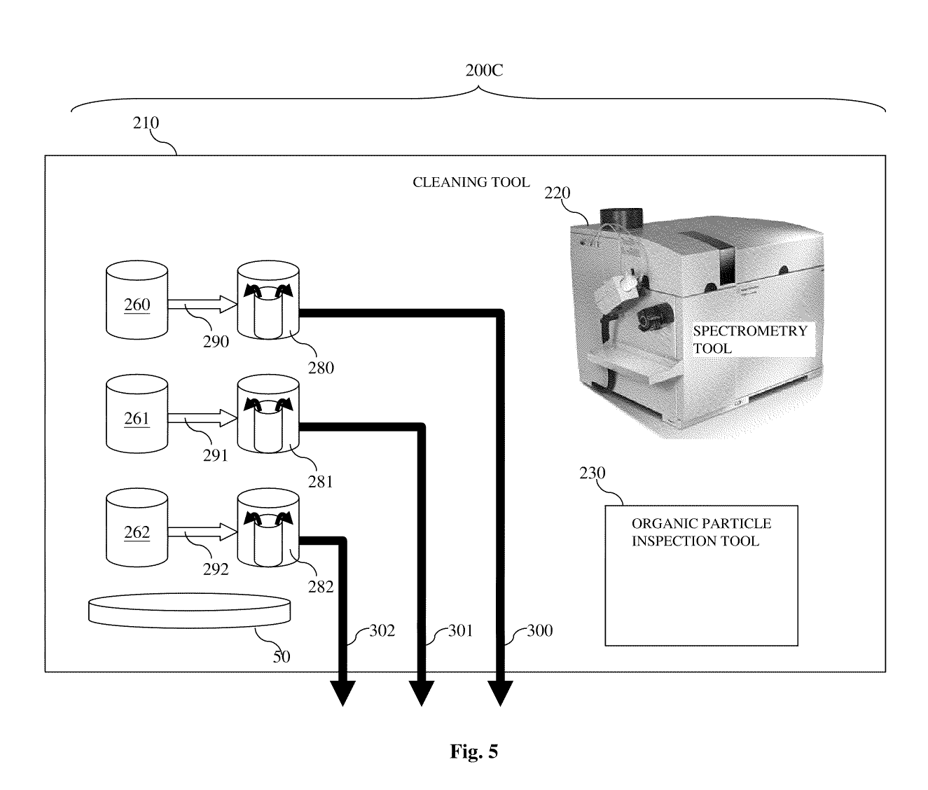

Referring now to FIG. 5, a diagrammatic view of an in-line cleaning and inspection system 200C according to another alternative embodiment is illustrated. In this embodiment, the spectrometry tool 220 and the organic particle inspection tool 230 are both integrated into the cleaning tool 210. In other words, the cleaning tool 210, the spectrometry tool 220, and the organic particle inspection tool 230 are now a single machine. Both the spectrometry tool 220 and the organic particle inspection tool 230 may be able to conduct their respective particle analyses by using a sample of the HPM cleaning solution (after its use for cleaning), or by using samples of the HPM cleaning solution and the APM cleaning solution (after their uses for cleaning).

It is understood that for each of the embodiments discussed above, additional processes may be performed to the wafer 50 after the cleaning process and the particle composition analysis process. For example, these additional processes may include deposition of passivation layers, formation of contacts, and formation of interconnect structures (e.g., lines and vias, metal layers, and interlayer dielectric that provide electrical interconnection to the device including the formed metal gate). For the sake of simplicity, these additional processes are not described herein.

The embodiments discussed above offer advantages over traditional inspection systems for high-k metal gate devices. It is understood, however, that other embodiments may offer different advantages, and that no particular advantage is required for all embodiments. One of the advantages is that the particle composition analysis is performed in-situ or in-line. For traditional inspection systems, the wafer is taken out of the cleaning tool after the cleaning, and another solution (such as a solution containing nitric acid HNO₃) is used to collect the samples of the contaminant particles for analysis in a spectrometry tool. Taking the wafer out of the cleaning tool wastes time (may take hours) and requires more handling processes. In contrast, the inspection systems discussed in the present application accomplishes the particle composition analysis while the wafer remains inside the cleaning tool. Thus, the systems described herein offer reduced analysis time and simplified handling processes.

Another advantage is that the systems described herein allow real-time feedback and adjustments to be made. For example, the spectrometry tool can report back the analysis results to the cleaning tool in real-time. In other words, the system can monitor the tool/chamber or wafer conditions in real-time. The cleaning tool may then make adjustments to those conditions “on the fly” for better contamination control.

In addition, with traditional inspection systems, the wafer is usually a test wafer and is typically discarded after the particle composition analysis is performed. This raises fabrication costs. Here, the wafer is not discarded but will undergo additional fabrication processes. As such, no wafer is wasted, thereby reducing fabrication costs.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A system, comprising:
a wafer-cleaning machine that cleans a surface of a semiconductor wafer using a cleaning solution; and
a spectrometry machine that is coupled to the wafer-cleaning machine and receives a portion of the cleaning solution from the wafer-cleaning machine, the portion of the cleaning solution collecting particles from the wafer during the cleaning;
wherein the spectrometry machine is operable to analyze a particle composition of a portion of the wafer based on the portion of the cleaning solution, while the wafer remains in the wafer-cleaning machine during the particle composition analysis.

2. The system of claim 1, wherein the wafer-cleaning machine and the spectrometry machine are integrated into a single machine.

3. The system of claim 1, wherein the cleaning solution includes hydrofluoric acid (HF), ammonium hydroxide (NH₄OH), and hydrochloric acid (HCl).

4. The system of claim 1, wherein:
the semiconductor wafer has high-k metal gate devices implemented thereon;
the particles collected by the cleaning solution include metal particles from the high-k metal gate devices; and
the spectrometry machine is operable to analyze an amount of metal particles in the cleaning solution.

5. The system of claim 1, further including an organic particle inspection machine that is coupled to the wafer-cleaning machine, the organic particles inspection machine being operable to receive the portion of the cleaning solution and analyze an organic particle content therein.

6. The system of claim 1, wherein:
the spectrometry machine is operable to feed results of the particle composition analysis back to the wafer-cleaning machine while the wafer remains in the wafer-cleaning machine; and
the wafer-cleaning machine is operable to make adjustments to cleaning the wafer based on the analysis results fed back from the spectrometry machine.

7. A system, comprising:
a wafer-cleaning apparatus that uses first, second, and third cleaning solutions in that order to clean a surface of a semiconductor wafer, the first, second, and third cleaning solutions being different from one another, the wafer having semiconductor gates formed thereon that contain a metal material; and
a particle-analysis apparatus that:
receives a sample of the third cleaning solution after the third cleaning solution has been used to clean the wafer; and
determines a content of the metal material in the sample of the third cleaning solution;
wherein the wafer stays in the wafer-cleaning apparatus while the particle-analysis apparatus receives the sample of the third cleaning solution and determines the content of the metal material therein.

8. The system of claim 7, further including an organic particle inspection apparatus, wherein the wafer-cleaning apparatus, the particle-analysis apparatus, and the organic particle inspection apparatus are all integrated into a single machine.

9. The system of claim 7, wherein the particle-analysis apparatus relays information regarding the content of the metal material to the wafer-cleaning apparatus on a real-time basis.

10. The system of claim 7, wherein:
the first cleaning solution includes hydrofluoric acid (HF);
the second cleaning solution includes ammonium hydroxide (NH₄OH); and
the third cleaning solution includes hydrochloric acid (HCl).

11. The system of claim 10, wherein the particle-analysis apparatus:
receives a sample of the second cleaning solution after the second cleaning solution has been used to clean the wafer; and
determines a content of the metal material in the sample of the second cleaning solution.

12. A method, comprising:
forming a gate of a semiconductor device, the gate containing a metal material;
cleaning the gate using a cleaning solution, the cleaning solution collecting particles from the gate during the cleaning; and
thereafter analyzing a portion of the cleaning solution for particle composition, the analyzing being carried out using an in-situ spectrometry machine.

13. The method of claim 12, wherein the semiconductor device is implemented on a wafer, and wherein:
the cleaning includes placing the wafer in a cleaning machine, the cleaning machine dispensing the cleaning solution; and
the analyzing is carried out in a manner so that the wafer remains in the cleaning machine during the analyzing.

14. The method of claim 12, further including: providing real-time feedback based on results of the analyzing.

15. The method of claim 12, wherein the cleaning solution includes first, second, and third cleaning agents that are each free of nitric acid (HNO₃) and different from one another, and wherein the cleaning includes:
cleaning the semiconductor device using the first cleaning agent;
discarding the first cleaning agent;
cleaning the semiconductor device using the second cleaning agent;
discarding the second agent;
thereafter cleaning the semiconductor device using the third cleaning agent;
saving a portion of the third cleaning agent as the portion of the cleaning solution that is used to carry out the analyzing.

16. The method of claim 15, wherein the cleaning is carried out in a manner so that:
the first cleaning agent includes hydrofluoric acid (HF);
the second cleaning agent includes ammonium hydroxide (NH₄OH); and
the third cleaning agent includes hydrochloric acid (HCl).

17. The method of claim 15, further including: after the cleaning, sending a portion of the third cleaning agent to the in-situ spectrometry machine for the analyzing.

18. The method of claim 12, wherein:
the semiconductor device is a high-k metal gate device;
the gate is one of: a high-k metal gate and a dummy poly gate; and
the particles collected by the cleaning solution include metal particles from the gate.

19. The method of claim 12, wherein the cleaning and the analyzing are carried out using a single machine that includes both the spectrometry machine as a component and a cleaning component that carries out the cleaning.

20. The method of claim 12, further including: after the analyzing, performing a semiconductor process on the semiconductor device.
